(19) United States
(12) Patent Application Publication
(10) Pub. No.: US 2011/0156739 A1
(43) Pub. Date: Jun. 30, 2011

(54) TEST KIT FOR TESTING A CHIP SUBASSEMBLY AND A TESTING METHOD BY USING THE SAME

(76) Inventors: Hsiao-Chuan CHANG, Kaohsiung City (TW); Ming-Hsiang CHENG, Kaohsiung City (TW); Tsung-Yueh TSAI, Kaohsiung (TW); Yi-Shao LAI, Yonghe City (TW); Ming-Kun CHEN, Yanchao Township (TW)

(21) Appl. No.: 12/651,067

(22) Filed: Dec. 31, 2009

(51) Int. Cl. G01R 31/02; G01R 1/06; G01R 31/26

(52) U.S. Cl. 324/756.02; 324/762.06

(57) ABSTRACT

A test kit for testing a chip subassembly and a testing method by using the same is provided. The chip subassembly includes at least two stacked chips each having a number of electric contacts is provided. The test kit includes a test socket and a test plate. The test socket is configured to electrically engage the electric contacts on a first side of the chip subassembly. The test plate has at least a number of first probes configured for electrically engaging the electric contacts on a second side of the chip subassembly. At least one of the test socket and the test plate has a number of second probes for electrically connecting the test socket and the test plate.

### BACKGROUND OF THE DISCLOSURE

1. Technical Field

The invention relates in general to a test kit and a testing method, and more particularly to a test kit for testing a chip subassembly and a testing method by using the same.

2. Description of the Related Art

As is well known, with a die as part of a wafer, the die (and the other dies of the wafer) is tested by means of probes for some functions of the die.

While such a wafer probe test with the die as part of a wafer is not a complete test of all functions of the die, it is helpful in eliminating the die which proves to be defective in such test. After that, the wafer is then sawed into individual dies, and each die is disposed on a substrate and then packaged as a semiconductor package. Complete functional testing is then undertaken on the die of the semiconductor package, and failed package are eliminated.

As for a multi-die semiconductor package, the testing procedure is similar to that described above. Assuming three dies passing the wafer probe test are packaged together as the multi-die semiconductor package, the overall functioning of the multi-die semiconductor package having three dies is tested. The multi-die semiconductor package is then eliminated if it fails such test. The failure may be due to the failure of one of the three dies, with the other two dies being properly functional. Due to the increased number of dies in the package, there is an increased possibility of including a die that, while passing the wafer probe test, would actually fail in more complete test for the multi-die semiconductor package, causing the entire device to be eliminated.

Because the yield of the multi-die semiconductor package and the manufacture cost of the multi-die semiconductor package highly depend upon the rate of eliminated device, how to screen out the failed device to improve the final yield of devices and reduce the manufacture cost thereof is an important issue to be resolved.

### SUMMARY OF THE DISCLOSURE

A test kit for testing a chip subassembly and a testing method by using the same is provided. The test kit and the testing method can screen out the failed device to improve the final yield of semiconductor packages and reduce the manufacture cost thereof.

According to a first aspect of the disclosure, a test kit for testing a chip subassembly comprising at least two stacked chips each having a number of electric contacts is provided. The test kit includes a test socket and a test plate. The test socket is configured to electrically engage the electric contacts on a first side of the chip subassembly. The test plate has at least a number of first probes configured for electrically engaging the electric contacts on a second side of the chip subassembly. At least one of the test socket and the test plate has a number of second probes for electrically connecting the test socket and the test plate.

According to a second aspect of the present disclosure, a method for testing a chip subassembly comprising at least two stacked chips each having a number of electric contacts is provided. The method includes the following steps. A test kit including a test socket and a test plate is provided. The test plate has at least a number of first probes. The electric contacts on a first side of the chip subassembly are electrically engaged with the test socket. The electric contacts on a second side of the chip subassembly are electrically engaged with the first probes of the test plate. The chip subassembly and the test plate are electrically connected by a number of second probes which are disposed at least on one of the test socket and the test plate. The function of the chip subassembly is tested.

The invention will become apparent from the following detailed description of the preferred but non-limiting embodiments. The following description is made with reference to the accompanying drawings.

### BRIEF DESCRIPTION OF THE DRAWINGS

FIG. 1 shows the side view of the semiconductor package which is related to the test kit of the disclosure.

FIG. 2 shows the top view of the semiconductor package shown in FIG. 1.

FIG. 3 illustrates a side view of a test kit for testing the chip subassembly according to a first embodiment of the disclosure.

FIG. 4A shows the chip subassembly having eight chips arranged in 2 by 2 matrix, which may be tested by using the test kit in FIG. 3.

FIG. 4B shows the chip subassembly having twenty one chips arranged in 3 by 3 matrix, which may be tested by using the test kit in FIG. 3.

FIG. 5 illustrates a side view of a test kit according to a second embodiment of the disclosure.

### DETAILED DESCRIPTION OF THE INVENTION

A test kit for testing a chip subassembly is disclosed. The chip subassembly includes at least two stacked chips each having a number of electric contacts. The kit includes at least a test socket and a test plate. The test socket is configured to electrically engage the electric contacts on a first side of the chip subassembly. The test plate has at least a number of first probes configured for electrically engaging the electric contacts on a second side of the chip subassembly. At least one of the test socket and the test plate has a number of second probes for electrically connecting the test socket and the test plate.

In this way, the function of the chip subassembly can be test before the chip subassembly is attached to a substrate to be packaged as a semiconductor package. If the chip subassembly does not pass the test, it is eliminated. Comparing with testing the whole device having the chip subassembly attached on the substrate, in which entire device is to be eliminated when failing the test, the test kit of this disclosure reduces the rate of eliminated semiconductor package, and therefore the yield of semiconductor packages is improved and the manufacture cost thereof is reduce.

### First Embodiment

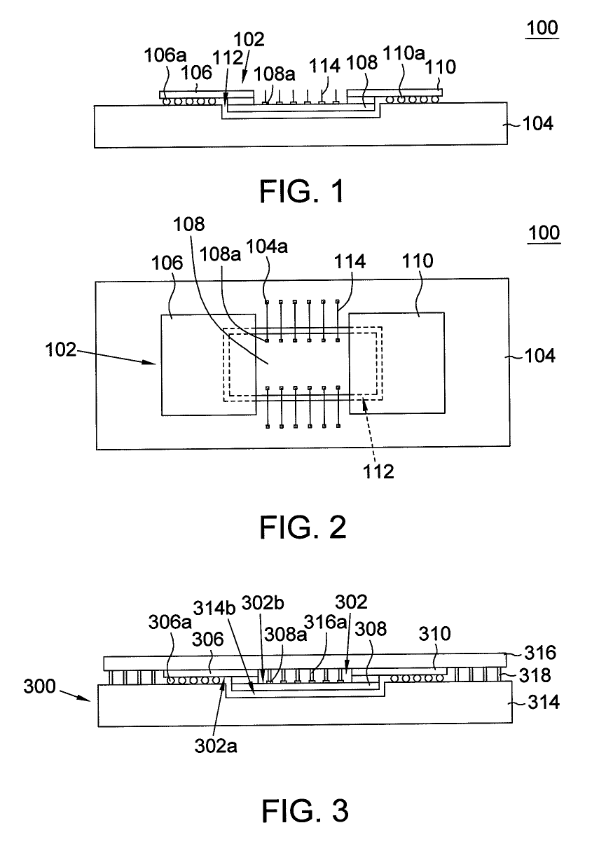

Assume the function of the semiconductor package 100 shown in FIG. 1 and FIG. 2 is to be test. FIG. 1 shows the side view of the semiconductor package 100 and FIG. 2 shows the top view of the semiconductor package 100. The semiconductor package 100 includes a chip subassembly 102 and a substrate 104. Take the chip subassembly 102 including chips 106, 108, and 110 for example. The chips 106 and 108 are in stacked relation, and the chips 108 and 110 are in stacked relation. The chip 108 is disposed between the chips 106 and 110. Each of the chips 106, 108, and 110 has electric contacts. For example, the chip 106 has a number of bumps 106a, the chip 108 has a number of wire pads 108a, and the chip 110 has a number of bumps 110a.

In the semiconductor package 100, the chip subassembly 102 is attached on the substrate 104. The substrate 104 has a cavity 112 for receiving the chip 108. The chip 106 is electrically connected to the substrate 104 through bumps 106a, the chip 108 is electrically connected to the substrate 104 through wires 114, and the chip 110 is electrically connected to the substrate 104 through the bumps 110a. The wires 114 electrically connect the wire pads 108a of the chip 108 and the pads 104a on the substrate 104.

Referring to FIG. 3, a side view of a test kit 300 for testing the chip subassembly 302 according to a first embodiment of the disclosure is illustrated. The chip subassembly 302 is substantially the same as the chip subassembly 102. The test kit 300 includes a test socket 314 and a test plate 316. The test socket 314 is configured to electrically engage the electric contacts on a first side 302a of the chip subassembly 302. The test plate 316 has a number of first probes 316a configured for electrically engaging the electric contacts on a second side 302b of the chip subassembly 302. At least one of the test socket 314 and the test plate 316 has a number of second probes 318 for electrically connecting the test socket 314 and the test plate 316. For example, the second probes 318 are disposed on the test socket 314 and touch the test plate 316 for electrically connecting, or the second probes 318 are disposed on the test plate 316 and touch the test socket 314 for electrically connecting.

The chip subassembly 302 has chips 306, 308, and 310. The chip 306 has several bumps 306a as the electric contacts, the chip 308 has several wire pads 308a as the electric contacts, and the chip 310 has several bumps 310a as the electric contacts. The bumps 306a and 310a are disposed on the first side 302a of the chip subassembly 302, and the wire pads 308a are disposed on the second side 302b of the chip subassembly 302. The test socket 314 electrically engages the bumps 306a and 310a of the chips 306 and 310 respectively, and the wire pads 308a of the chip 308 are engaged with the first probes 316a of the test plate 316.

Besides, the test socket 314 has a cavity 314b for receiving part of the chip subassembly 302, for example, for receiving the chip 308. The chips 306, 308, and 310 of the chip subassembly 302, for example, have the function of proximity communication. In order to achieve the function of proximity communication, part of the chips 306 and 308 are placed face-to-face in a manner that aligns the transmitter circuit of one chip with the receiver circuit of the other in extremely close proximity, for example, with only microns of separation between them. The signals between the transmitter circuit and the receiver circuit may be transmitted by inductive or capacitive coupling with low overall communication cost.

For example, the chip 306 has signal pads (not shown) formed on a major surface of the chip 306, the chip 308 has signal pads (not shown) formed on a major surface of the chip 308, and the chip 310 has signal pads (not shown) formed on a major surface of the chip 310. The chip 308 are arranged in face-to-face manner with the chip 306 and the chip 310 so that at least some of the signal pads of the chip 308 are capacitively coupled to at least some of the signal pads of the chip 306 and at least some of the signal pads of the chip 310. The major surface of the chip 308 is spaced apart from the major surface of the chip 306 and the major surface of the chip 310.

Take transmission by capacitive coupling for example. Part of the signal pads of the chip 308 and the signal pads of the chip 306 are aligned with each other, and part of the signal pads of the chip 308 and the signal pads of the chip 310 are aligned with each other. Since the pads are not in physical contact with each other, there are capacitances between the signal pads of the chip 306 and the signal pads of the chip 308, and between the signal pads of the chip 308 and the signal pads of the chip 310. It is this capacitive coupling that provides signal paths between the chip 306 and the chip 308 and between the chip 308 and the chip 310. Changes in the electrical potential of the surface metal of a signal pad cause corresponding changes in the electrical potential of the metal comprising the corresponding signal pad. Suitable drivers of the transmitter circuit and sensing circuits of the receiver circuit in the respective chip make communication through this small capacitance possible.

When testing the chip subassembly, the testing method includes the following steps. Firstly, the test kit 300 is provided. Next, the electric contacts on the first side 302a of the chip subassembly 302 are electrically engaged with the test socket 314. After that, the electric contacts on the second side 302b of the chip subassembly 302 are electrically engaged with the first probes 316a of the test plate 316. Then, the chip subassembly 302 and the test plate 316 are electrically engaged with the second probes 318 which are disposed at least on one of the test socket 314 and the test plate 316. After that, the function of the chip subassembly 302 is tested.

Preferably, press can be applied on the test plate 316 for fixing the chip subassembly 302 in the test kit 300. The electrical signals for testing the chip 306 can be transmitted between the chip 306 and the test socket 314 through the bumps 306a. The electrical signals for testing the chip 308 can be transmitted between the chip 308 and the test socket 314 through the first probes 316a, the test plate 316, and second probes 318. The electrical signals for testing the chip 310 can be transmitted between the chip 310 and the test socket 314 through the bumps 310a. A testing system (not shown) can be further electrically connected to at least one of the test socket 314 and the test plate 316 for providing the testing signals and analysis the testing result. The function of chip subassembly 302, which can be further electrically connected to a substrate by bumps on the first side 302a and by wires disposed the second side 302b, can be well tested by using the test kit 300.

If the chip subassembly 302 fails during the testing, the chip subassembly 302 is discarded. Comparing with the testing method of testing the entire semiconductor package and eliminating the entire semiconductor package if it fails, the testing method tests the function of the chip subassembly 302 firstly and separately, and the chip subassembly 302 which fails is discarded and is not packaged with the substrate. Consequently, the semiconductor package having the chip subassembly 302 and the substrate will has higher possibility of functioning properly. The rate of eliminated semiconductor package is reduced, and therefore the yield of semiconductor packages is improved and the manufacture cost thereof is reduced.

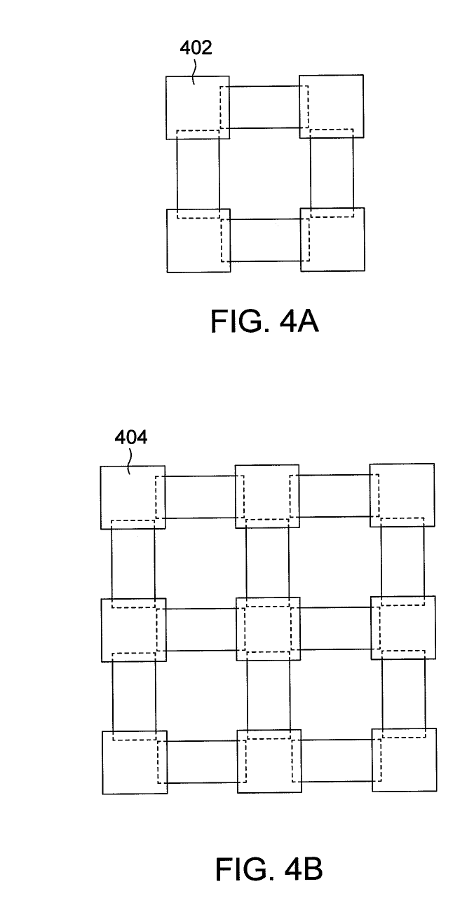

The test kit 300 can also to be used in testing a chip subassembly of other type after re-designed correspondingly. For example, the test kit 300 can also to be used in testing the chip subassembly having a number of chips arranged in matrix, for example, the chips arranged in matrix as shown in FIG. 4A or FIG. 4B. In FIG. 4A, the chip subassembly 400 has eight chips 402 arranged in 2 by 2 matrix. In FIG. 4B, the chip subassembly 400 has twenty one chips 404 arranged in 3 by 3 matrix. Two adjacent chips are partially overlapped to each other in stacked relation for the function of proximity communication, for example.

### Second Embodiment

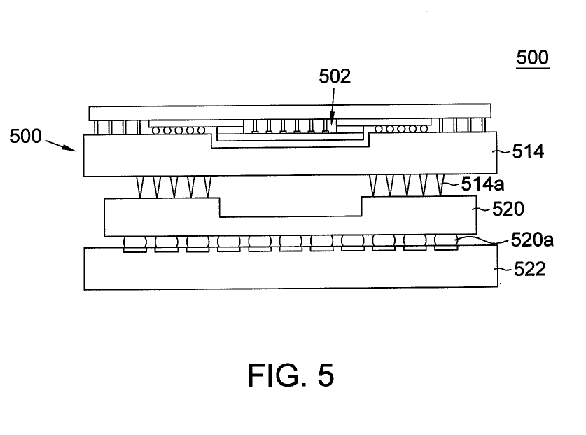

Referring to FIG. 5, a side view of a test kit 500 for testing the chip subassembly 502 according to a second embodiment of the disclosure is illustrated. The difference between the test kit 300 of the first embodiment and the test kit 500 of the second embodiment are described as follows.

Comparing with the test kit 300, the test kit 500 further includes a golden substrate 520 and a test substrate 522. The test substrate 522 is electrically connected to the golden substrate 520. For example, the golden substrate 520 has a number of bumps 520a for electrically connecting the test substrate 522 with the golden substrate 520. The test socket 514 further has a number of third probes 514a for electrically connecting the test socket 514 and the golden substrate 520.

The golden substrate 520 is substantially the same with the substrate 104, and the golden substrate 520 is the substrate which functions properly.

In the first embodiment, the test socket 314 simulates the function of the golden substrate 520 during testing. In the second embodiment, the design of the test socket 314 is simplifier while simulating the function of the golden substrate 520 is not necessary for the test socket 514.

During test the chip subassembly 502, the electrical signals for testing can further be transmitted between test socket 514 and the golden substrate 520 through the third probes 514a, and between the golden substrate 520 and the test substrate 522 through the bumps 520a. A testing system (not shown) can be electrically connected to at least one of the test plate 316, the test socket 514, and the test substrate 522 for providing testing signals and analysis the testing result. The failed devices can be screened out by using the test kit 500 and the testing method, and the yield of semiconductor packages is improved and the manufacture cost thereof is reduced.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A test kit for testing a chip subassembly comprising at least two stacked chips each having a plurality of electric contacts, the test kit comprising:
a test socket, configured to electrically engage the electric contacts on a first side of the chip subassembly; and
a test plate, having at least a plurality of first probes configured for electrically engaging the electric contacts on a second side of the chip subassembly;
wherein at least one of the test socket and the test plate has a plurality of second probes for electrically connecting the test socket and the test plate.

2. The test kit according to claim 1, further comprising:
a golden substrate; and
a test substrate, electrically connected to the golden substrate;
wherein the test socket has a plurality of third probes for electrically connecting the test socket and the golden substrate.

3. The test kit according to claim 1, wherein the chip subassembly comprising a first chip, a second chip, and a third chip, the second chip is disposed between the first chip and third chip, the electric contacts of the first chip comprising a plurality of bumps, and the electric contacts of the second chip comprising a plurality of wire pads, the electric contacts of the third chip comprising a plurality of bumps, the bumps of the first and third chips are engaged with the test socket, and the wire pads of the second chip is engaged with the first probes of the test plate.

4. The test kit according to claim 1, wherein the test socket has a cavity for receiving part of the chip subassembly.

5. The test kit according to claim 1, wherein the chip subassembly comprising chips having the function of proximity communication.

6. The test kit according to claim 1, wherein the chip subassembly comprising a plurality of chips arranged in matrix.

7. A method for testing a chip subassembly comprising at least two stacked chips each having a plurality of electric contacts, the method comprising:
providing a test kit, the test kit comprising a test socket and test plate, the test plate having at least a plurality of first probes;
electrically engaging the electric contacts on a first side of the chip subassembly with the test socket;
electrically engaging the electric contacts on a second side of the chip subassembly with the first probes of the test plate; and
electrically connecting the chip subassembly and the test plate by a plurality of second probes which are disposed at least on one of the test socket and the test plate; and
testing the function of the chip subassembly.

8. The method according to claim 7, wherein the test kit further comprising a golden substrate and a test substrate, the test substrate is electrically connected to the golden substrate, the test socket has a plurality of third probes, the test socket and the golden substrate are electrically connected by the third probes.

9. The method according to claim 7, wherein the chip subassembly comprising a first chip, a second chip, and a third chip, the second chip is disposed between the first chip and third chip, the electric contacts of the first chip comprising a plurality of bumps, and the electric contacts of the second chip comprising a plurality of wire pads, the electric contacts of the third chip comprising a plurality of bumps, the bumps of the first and third chips are engaged with the test socket, and the wire pads of the second chip is engaged with the first probes of the test plate.

10. The method according to claim 7, wherein the test socket has a cavity for receiving part of the chip subassembly.

11. The method according to claim 7, wherein the chip subassembly comprising chips having the function of proximity communication.

12. The method according to claim 7, wherein the chip subassembly comprising a plurality of chips arranged in matrix.
